(19) United States
(12) Patent Application Publication
(10) Pub. No.: US 2021/0358782 A1
(43) Pub. Date: Nov. 18, 2021

(54) SUBSTRATE TRANSFER MODULE AND SEMICONDUCTOR PROCESSING SYSTEM

(71) Applicant: Piotech Inc., Shenyang (CN)

(72) Inventors: Jason Lee Tian, Shenyang (CN); Zhuo Wang, Shenyang (CN)

(21) Appl. No.: 17/234,047

(22) Filed: Apr. 19, 2021

(30) Foreign Application Priority Data
May 15, 2020 (CN) 202010418016.X

(51) Int. Cl. H01L 21/67; H01L 21/677

(52) U.S. Cl. CPC H01L 21/67196; H01L 21/6773; H01L 21/67201; H01L 21/67766; H01L 21/67745

(57) ABSTRACT

This application relates to a substrate transfer module and a semiconductor processing system. The substrate transfer module includes: a transfer chamber, having a first end and a second end in a length direction, and having a first side and a second side in a width direction; a slide rail, disposed in the transfer chamber, and extending in the length direction of the transfer chamber; and a mechanical arm, disposed on the slide rail and having an extending arm portion, wherein the mechanical arm is operable to move along the slide rail in the length direction of the transfer chamber to transfer a substrate between an equipment front end module (EFEM) and a processing chamber, the EFEM is located at the first end of the transfer chamber, and the processing chamber is located on the first side or the second side of the transfer chamber.

### BACKGROUND OF THE INVENTION

### 1. Field of the Invention

This application generally relates to the field of semiconductor manufacturing, and more specifically, to a semiconductor processing system and a substrate transfer module therein.

### 2. Description of the Related Art

A semiconductor processing system generally includes several parts such as an equipment front end module (EFEM), a load lock (LL) module, a transfer module (TM), and a processing module (PM). With the development of semiconductor manufacturing technologies, a production capacity of the semiconductor processing system and an integrated production capacity of a production machine need to be improved. This requires an increase in the maximum quantity of substrates that can be simultaneously processed by the semiconductor processing system. The objective may be achieved by increasing a quantity of processing chambers carried in the semiconductor processing system. Therefore, how to improve the scalability of the semiconductor processing system and effectively improve the integration level of the system becomes a problem that needs to be emphatically considered in the design of the semiconductor processing system.

### SUMMARY OF THE INVENTION

To resolve the foregoing problem, in an implementation of this application, a substrate transfer module is provided. The substrate transfer module includes a transfer chamber, a slide rail, and a mechanical arm. The transfer chamber has a first end and a second end in a length direction, and has a first side and a second side in a width direction. The slide rail is disposed in the transfer chamber, and extends in the length direction of the transfer chamber. The mechanical arm is disposed on the slide rail and has an extending arm portion. The mechanical arm is operable to move along the slide rail in the length direction of the transfer chamber, to transfer a substrate between an equipment front end module (EFEM) and a processing chamber. The EFEM is located at the first end of the transfer chamber, and the processing chamber is located on the first side or the second side of the transfer chamber.

In some embodiments, the substrate transfer module further includes a sliding bracket. The sliding bracket is disposed on the slide rail, and is operable to move along the slide rail in the length direction of the transfer chamber. The mechanical arm is disposed on the sliding bracket.

In some embodiments, the first side and the second side of the transfer chamber are provided with a plurality of valves, and a front end of the arm portion of the mechanical arm is operable to pass through the plurality of valves.

In some embodiments, the transfer chamber includes a vacuum transfer chamber. The transfer chamber may be connected to the processing chamber through a valve on the first side or the second side. The mechanical arm is operable to: place a to-be-processed substrate into the processing chamber through the valve, and take a processed substrate from the processing chamber through the valve. The transfer chamber may be connected to a load lock (LL) chamber located between the transfer chamber and the EFEM through a vacuum valve on the first end. The mechanical arm is operable to: take a to-be-processed substrate from the LL chamber through the vacuum valve, and place a processed substrate into the LL chamber through the vacuum valve.

In some embodiments, the transfer chamber includes an atmospheric transfer chamber. The transfer chamber is connected to the EFEM, and the mechanical arm is operable to: take a to-be-processed substrate from the EFEM, and place a processed substrate into the EFEM. the transfer chamber may be connected to a load lock (LL) chamber located between the transfer chamber and the processing chamber through an atmospheric valve on the first side or the second side. The mechanical arm is operable to: place a to-be-processed substrate into the LL chamber through the atmospheric valve, and take a processed substrate from the LL chamber through the atmospheric valve.

In another implementation of this application, a semiconductor processing system is provided. The semiconductor processing system may include the substrate transfer module disclosed in this application, an EFEM, and a processing chamber.

In some embodiments, the substrate transfer module further includes a sliding bracket. The sliding bracket is disposed on the slide rail, and is operable to move along the slide rail in the length direction of the transfer chamber. The mechanical arm is disposed on the sliding bracket.

In some embodiments, the first side and the second side of the transfer chamber are provided with a plurality of valves, and a front end of the arm portion of the mechanical arm is operable to pass through the plurality of valves.

In some embodiments, the transfer chamber includes a vacuum transfer chamber. The transfer chamber may be connected to the processing chamber through a valve on the first side or the second side. The mechanical arm is operable to: place a to-be-processed substrate into the processing chamber through the valve, and take a processed substrate from the processing chamber through the valve. The semiconductor processing system further includes: a load lock (LL) chamber located between the transfer chamber and the EFEM. The transfer chamber may be connected to the LL chamber through a vacuum valve on the first end, and the LL chamber may be connected to the EFEM through an atmospheric valve. The mechanical arm is operable to: take a to-be-processed substrate from the LL chamber through the vacuum valve, and place a processed substrate into the LL chamber through the vacuum valve. The EFEM may include a second mechanical arm. The second mechanical arm is operable to: place a to-be-processed substrate into the LL chamber through the atmospheric valve, and take a processed substrate from the LL chamber through the atmospheric valve. The EFEM may include a second slide rail, and the second mechanical arm is disposed on the second slide rail and is operable to move along the second slide rail.

In some embodiments, the transfer chamber includes an atmospheric transfer chamber. The transfer chamber is connected to the EFEM, and the mechanical arm is operable to: take a to-be-processed substrate from the EFEM, and place a processed substrate into the EFEM. The EFEM may u) include a second mechanical arm. The second mechanical arm is operable to: transfer a to-be-processed substrate from a substrate carrier to the mechanical arm, and transfer a processed substrate from the mechanical arm to the substrate carrier. The EFEM may include a second slide rail, and the second mechanical arm is disposed on the second slide rail and is operable to move along the second slide rail. The semiconductor processing system further includes a load lock (LL) chamber located between the transfer chamber and the processing chamber. The transfer chamber is connected to the LL chamber through an atmospheric valve on the first side or the second side, and the LL chamber is connected to the processing chamber through a vacuum valve. The mechanical arm is operable to: place a to-be-processed substrate into the LL chamber through the atmospheric valve, and take a processed substrate from the LL chamber through the atmospheric valve. The LL chamber includes an additional mechanical arm. The additional mechanical arm is operable to: place a to-be-processed substrate into the processing chamber through the vacuum valve, and take a processed substrate from the processing chamber through the vacuum valve.

In some embodiments, the processing chamber includes an even quantity of processing stations.

Details of one or more examples of this application are described in the accompanying drawings and descriptions below. Other features, objectives, and advantages are apparent according to the descriptions, the accompanying drawings, and the claims.

### BRIEF DESCRIPTION OF THE DRAWINGS

The disclosure in this specification mentions and includes the following figures:

FIG. 1 illustrates a schematic structural diagram of a semiconductor processing system according to some embodiments of this application; and

FIG. 2 illustrates a schematic structural diagram of a semiconductor processing system according to some other embodiments of this application.

As customary, various features described in the figures may not be drawn to scale. Therefore, for clarity, the sizes of the various features may be increased or reduced arbitrarily. Shapes of the components illustrated in the figures are merely exemplary shapes, and are not intended to limit actual shapes of the components. In addition, for clarity, implementation solutions illustrated in the figures may be simplified. Therefore, the figures may not describe all components of given equipment or apparatus. Finally, the same reference numerals may be used to represent the same features throughout this specification and the figures.

### PREFERRED EMBODIMENT OF THE PRESENT INVENTION

The following more completely describes the present invention with reference to the figures, and specified exemplary specific embodiments are displayed by using examples. However, the claimed subject matter may be specifically implemented in many different forms. Therefore, the construction of the claimed subject matter that is covered or applied for is not limited to any of the exemplary specific embodiments disclosed in this specification. The exemplary specific embodiments are merely examples. Similarly, the present invention aims to provide a proper and broad scope for the claimed subject matter that is applied for or covered.

The phrase “in an embodiment” or “according to an embodiment” used in this specification does not necessarily refer to the same specific embodiment, and does not mean that the technical solution claimed to be protected has to include all the features described in the embodiments, and the phrase “in (some/certain) other embodiments” or “according to (some/certain) other embodiments” used in this specification does not necessarily refer to different specific embodiments. An objective is that, for example, the claimed subject matter includes a combination of all or a part of the exemplary specific embodiments. The terms “include” and “comprise” in this specification are used in an open-ended manner, and therefore, should be interpreted as “include, but not limited to . . . ”. The meanings of “upper” and “lower” in this specification are not intended to be limited to a relationship directly presented in the figures, and should include descriptions having an explicit correspondence, for example, “left” and “right”, or contrary of “upper” and “lower”. The word “substrate” in this specification should be understood to be used interchangeably with the terms such as “base plate”, “wafer”, “crystal wafer”, “chip”, or “silicon wafer”. Some terms are used to refer to specific system components in this specification. As understood by a person skilled in the art, different enterprises may use different names to refer to these system components.

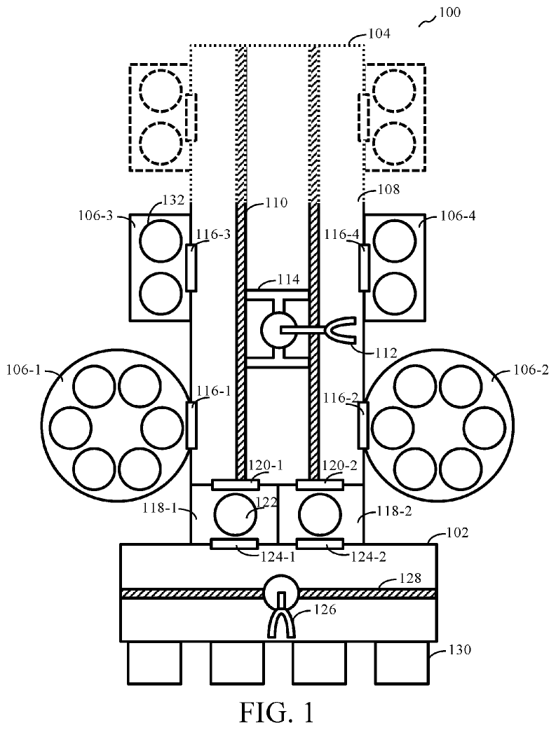

FIG. 1 illustrates a schematic structural diagram of a semiconductor processing system 100 according to some embodiments of this application. The semiconductor processing system 100 includes an EFEM 102, load lock (LL) chambers 118-1 and 118-2 (collectively referred to as LL chambers 118), a substrate transfer module 104, and processing chambers 106-1, 106-2, 106-3, and 106-4 (collectively referred to as processing chambers 106). Although FIG. 1 shows a specific quantity of LL chambers and processing chambers, a person skilled in the art should understand that, the semiconductor processing system 100 may include fewer or more LL chambers and processing chambers.

The substrate transfer module 104 includes a transfer chamber 108, a slide rail 110, and a mechanical arm 112. The transfer chamber 108 has a first end (for example, a lower end shown in FIG. 1) and a second end (for example, an upper end shown in FIG. 1) in a length direction (for example, a vertical direction shown in FIG. 1), and has a first side (for example, a left side shown in FIG. 1) and a second side (for example, a right side shown in FIG. 1) in a width direction (for example, a horizontal direction shown in FIG. 1). The size of the transfer chamber 108 in the length direction is generally greater than the size in the width direction. A dashed-line part in FIG. 1 represents that the transfer chamber 108 may be expanded arbitrarily in the length direction as required.

The slide rail 110 is disposed in the transfer chamber 108, and extends in the length direction of the transfer chamber 108. A dashed-line part in FIG. 1 represents that the slide rail 110 may be extended arbitrarily in the length direction of the transfer chamber 108 as required. In the example of FIG. 1, the slide rail 110 includes two rails parallel to each other. Two rails may achieve higher stability than a single rail. It should be understood that, in other embodiments, the slide rail 110 may include rails with another quantity and/or in another form.

The mechanical arm 112 is disposed on the slide rail 110, and is operable to move along the slide rail 110 in the length direction of the transfer chamber 108, so as to transfer a substrate between the EFEM 102 located at the first end of the transfer chamber 108 and a processing chamber 106 located on the first side or the second side of the transfer chamber 108. For example, by moving along the slide rail 110 to different positions, the mechanical arm 112 may transfer the substrate from the EFEM 102 to any one of the processing chambers 106, or transfer the substrate from any one of the processing chambers 106 to the EFEM 102, or transfer the substrate from one of the processing chambers 106 to another of the processing chambers 106. In some embodiments of this application, a sliding bracket 114 is disposed on the slide rail 110, and the mechanical arm 112 is disposed on the sliding bracket 114. The sliding bracket 114 is operable to move along the slide rail 110 in the length direction of the transfer chamber 108, and the mechanical arm 112 may move together with the sliding bracket 114. In some embodiments, the mechanical arm 112 is fixedly mounted on the sliding bracket 114. That is, the mechanical arm 112 cannot move on the sliding bracket 114. In some other embodiments, the mechanical arm 112 is movably mounted on the sliding bracket 114. That is, the mechanical arm 112 can move on the sliding bracket 114 in a small range. In other embodiments of this application, the mechanical arm 112 may be disposed on the slide rail 110 and move along the slide rail 110 in other manners instead of using the sliding bracket 114.

The mechanical arm 112 has an extending arm portion. Because the arm portion is stretchable in length (for example, the arm portion may include a foldable or stretchable portion), a front end of the arm portion may extend to a specified position (for example, within the LL chamber 118 or the processing chamber 106). The front end of the arm portion may include an apparatus such as a vane, a paddle, a fork or a jig for supporting or holding the substrate. The mechanical arm 112 may include one arm portion, or may include a plurality of arm portions to simultaneously transfer a plurality of substrates. In a case that the slide rail 110 is relatively long and the mechanical arm 112 may need to move a relatively long distance along the slide rail 110 to transfer the substrate, the transfer stability of the mechanical arm 112 and the equipment reliability need to be improved. For example, stable transfer and accurate positioning can be achieved by means of carefully designing structures of the slide rail 110 and the mechanical arm 112 and a connection structure between the slide rail and the mechanical arm, adopting a sensor(s), signal coordination, air flow control in a chamber and the like.

Two sides of the transfer chamber 108 may be provided with a plurality of valves 116-1, 116-2, 116-3, and 116-4 (collectively referred to as valves 116). Although FIG. 1 shows a specific quantity of valves 116, a person skilled in the art should understand that, the semiconductor processing system 100 may include fewer or more valves 116. The transfer chamber 108 is connected to the corresponding processing chamber 106 through the valve 116. For example, the transfer chamber 108 is connected to the processing chamber 106-1 through the valve 116-1, the transfer chamber 108 is connected to the processing chamber 106-2 through the valve 116-2, the transfer chamber 108 is connected to the processing chamber 106-3 through the valve 116-3, and the transfer chamber 108 is connected to the processing chamber 106-4 through the valve 116-4. Although each processing chamber 106 has only one valve 116 in the example of FIG. 1, it should be understood that, in other embodiments, the processing chamber 106 may have more than one valve 116. For example, the transfer chamber 108 may be connected to the processing chamber 106-3 through two valves, wherein each valve is aligned with a corresponding processing station 132 in the processing chamber 106-3. The front end of the arm portion of the mechanical arm 112 is operable to pass through the valve 116 to enter the corresponding processing chamber 106, so as to place a to-be-processed substrate into the processing chamber 106 (for example, to a processing station in the processing chamber) or take a processed substrate from the processing chamber 106 (for example, from a processing station in the processing chamber).

FIG. 1 shows the processing chambers 106-1 and 106-2 each including six processing stations, and the processing chambers 106-3 and 106-4 each including two processing stations. A dashed-line part in FIG. 1 represents that any quantity of valves and corresponding processing chambers may be disposed on both sides of the extending portion of the transfer chamber 108 in the length direction. Therefore, by increasing the length of the transfer chamber 108 and the length of the corresponding slide rail 110, a quantity of processing chambers carried in the semiconductor processing system 100 may be increased, thereby improving the integration level of the system and increasing the production capacity. A person skilled in the art should understand that, the semiconductor processing system 100 may include processing chambers with other shapes and/or configurations, and the processing chambers may include other quantities of processing stations. In some embodiments, the processing chamber may include an even quantity of processing stations. Positions, quantities, types, and the like of the valves and the processing chambers on the two sides of the transfer chamber 108 may be the same, or may be different. The processing chamber in the semiconductor processing system 100 may be used to perform various semiconductor manufacturing processes such as deposition, etching, and cleaning on the substrate. The manufacturing processes performed by the processing chambers may be the same, or may be different.

The transfer chamber 108 shown in FIG. 1 is located between the LL chamber 118 and the processing chamber 106, and therefore is a vacuum transfer chamber. The chamber may be caused to be in a vacuum environment by using a vacuum pump. The LL chamber 118 is located between the transfer chamber 108 and the EFEM 102. In the example of FIG. 1, the LL chambers 118-1 and 118-2 are two separate chambers, and the two chambers may perform air extraction or air admission independently of each other. Each chamber may receive one substrate. In other embodiments, one LL chamber may receive a plurality of substrates. The transfer chamber 108 is connected to the LL chamber 118-1 through a vacuum valve 120-1 on the first end, and the transfer chamber 108 is connected to the LL chamber 118-2 through a vacuum valve 120-2 on the first end. The front end of the mechanical arm 112 in the transfer chamber 108 is operable to pass through the vacuum valve 120 to enter the corresponding LL chamber 118, so as to take a to-be-processed substrate from the LL chamber 118 (for example, from a platform 122 in the LL chamber) or place a processed substrate into the LL chamber 118 (for example, to a platform 122 in the LL chamber). In the example of FIG. 1, because the first end of the transfer chamber 108 is connected to two side-by-side LL chambers 118, the width of the transfer chamber 108 needs to be greater than the diameters of two substrates plus a certain gap width. For example, the width of the transfer chamber 108 is approximately 75 cm.

The LL chamber 118-1 is connected to the EFEM 102 through an atmospheric valve 124-1, and the LL chamber 118-2 is connected to the EFEM 102 through an atmospheric valve 124-2. The EFEM 102 may include a mechanical arm 126. The mechanical arm 126 is operable to transfer the substrate between a substrate carrier 130 and the LL chamber 118. The mechanical arm 126 has an extending arm portion. Because the arm portion is stretchable in length (for example, the arm portion may include a foldable or stretchable portion), a front end of the arm portion may extend to a specified position (for example, within the LL chamber 118 or the substrate carrier 130). The front end of the arm portion may include an apparatus such as a vane, a paddle, a fork or a jig for supporting or holding the substrate. The mechanical arm 126 may include one arm portion, or may include a plurality of arm portions to simultaneously transfer a plurality of substrates. FIG. 1 shows four substrate carriers 130 located on one end of the EFEM 102. It should be understood that, additionally or alternatively, the substrate carrier(s) 130 may be disposed on other position(s) (for example, on the two sides) of the EFEM 102, and fewer or more substrate carriers 130 may be optionally included. The mechanical arm 126 is operable to: take a to-be-processed substrate from any substrate carrier 130 through a door (not shown) between the EFEM 102 and the substrate carrier 130, and then place the to-be-processed substrate into the LL chamber 118 through the atmospheric valve 124. The mechanical arm 126 is further operable to: take the processed substrate from the LL chamber 118 through the atmospheric valve 124, and then place the processed substrate into any substrate carrier 130 through the door (not shown) between the EFEM 102 and the substrate carrier 130.

In some embodiments, the EFEM 102 may include a slide rail 128. The mechanical arm 126 may be disposed on the slide rail 128, and is operable to move along the slide rail 128 to different positions to transfer the substrates. The mechanical arm 126 may be disposed on the slide rail 128 by using a bracket (not shown) or another connection structure. In the example of FIG. 1, the slide rail 128 includes one rail. It should be understood that, in other embodiments, the slide rail 128 may include rails with another quantity and/or in another form. In other embodiments of this application, the mechanical arm 126 may move in another manner instead of using the slide rail, or the mechanical arm 126 does not move, but transfers the substrate only by using the extending arm portion.

A manner of transferring a substrate in the semiconductor processing system 100 is described below with reference to FIG. 1. When a substrate needs to be processed, the to-be-processed substrate is disposed in the substrate carrier 130. The corresponding vacuum valve 120 of the LL chamber 118 is closed, the corresponding atmospheric valve 124 is opened, and the LL chamber 118 is restored to an atmospheric environment. The mechanical arm 126 takes the to-be-processed substrate from the substrate carrier 130, and transfers the to-be-processed substrate to the LL chamber 118 through the atmospheric valve 124. Then, the atmospheric valve 124 is closed. After the LL chamber 118 is vacuumized, the corresponding vacuum valve 120 is opened. The mechanical arm 112 moves to a position near the first end of the transfer chamber 108, takes the to-be-processed substrate from the LL chamber 118 through the vacuum valve 120, then moves along the slide rail 110 to a position near the processing chamber 106 in which the required processing is to be performed, and transfers the to-be-processed substrate to the processing chamber 106 through the corresponding valve 116. After the valve 116 is closed, the required processing is performed on the substrate. After the processing is completed, the valve 116 is opened, and the mechanical arm 112 takes the processed substrate from the processing chamber 106. If the substrate needs to be further processed in another processing chamber, the mechanical arm 112 may transfer the substrate to the another processing chamber; otherwise, the mechanical arm 112 moves to a position near the first end of the transfer chamber 108, and transfers the processed substrate to the LL chamber 118 through the vacuum valve 120. Then, the corresponding vacuum valve 120 of the LL chamber 118 is closed, the corresponding atmospheric valve 124 is opened, and the LL chamber 118 is restored to an atmospheric environment. The mechanical arm 126 takes the processed substrate from the LL chamber 118 through the atmospheric valve 124, and transfers the processed substrate to the substrate carrier 130.

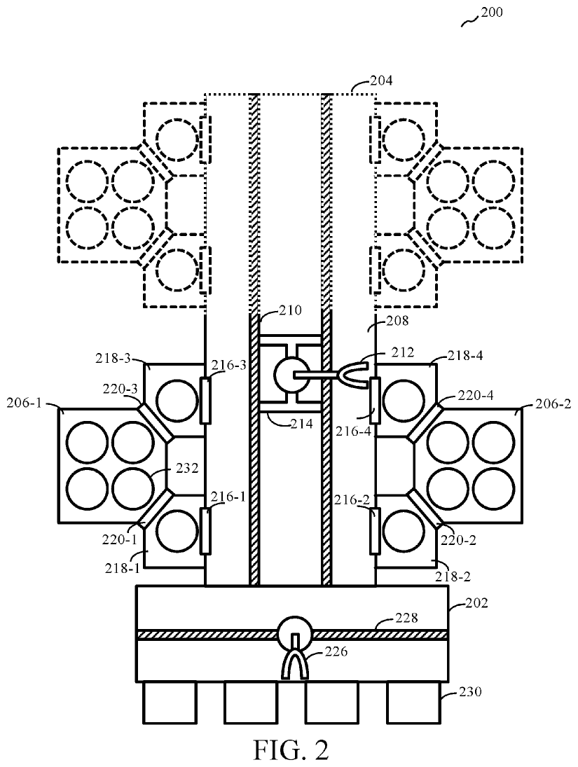

FIG. 2 illustrates a schematic structural diagram of a semiconductor processing system 200 according to some other embodiments of this application. The semiconductor processing system 200 includes an EFEM 202, a substrate transfer module 204, LL chambers 218-1, 218-2, 218-3 and 218-4 (collectively referred to as LL chambers 118), and processing chambers 206-1 and 206-2 (collectively referred to as processing chambers 206). Although FIG. 2 shows a specific quantity of LL chambers and processing chambers, a person skilled in the art should understand that, the semiconductor processing system 100 may include fewer or more LL chambers and processing chambers.

The substrate transfer module 204 includes a transfer chamber 208, a slide rail 210, and a mechanical arm 212. The transfer chamber 208 has a first end (for example, a lower end shown in FIG. 2) and a second end (for example, an upper end shown in FIG. 2) in a length direction (for example, a vertical direction shown in FIG. 2), and has a first side (for example, a left side shown in FIG. 2) and a second side (for example, a right side shown in FIG. 2) in a width direction (for example, a horizontal direction shown in FIG. 2). The size of the transfer chamber 208 in the length direction is generally greater than the size in the width direction. A dashed-line part in FIG. 2 represents that the transfer chamber 208 may be expanded arbitrarily in the length direction as required.

The slide rail 210 is disposed in the transfer chamber 208, and extends in the length direction of the transfer chamber 208. A dashed-line part in FIG. 2 represents that the slide rail 210 may be extended arbitrarily in the length direction of the transfer chamber 208 as required. In the example of FIG. 2, the slide rail 210 includes two rails parallel to each other. Two rails may achieve higher stability than a single rail. It should be understood that, in other embodiments, the slide rail 210 may include rails with another quantity and/or in another form.

The mechanical arm 212 is disposed on the slide rail 210, and is operable to move along the slide rail 210 in the length direction of the transfer chamber 208, so as to transfer a substrate between the EFEM 202 located at the first end of the transfer chamber 208 and a processing chamber 206 located on the first side or the second side of the transfer chamber 208. For example, by moving along the slide rail 210 to different positions, the mechanical arm 212 may transfer the substrate from the EFEM 202 to any one of the processing chambers 206, or transfer the substrate from any one of the processing chambers 206 to the EFEM 202, or transfer the substrate from one of the processing chambers 206 to another of the processing chambers 206. In some embodiments of this application, a sliding bracket 214 is disposed on the slide rail 210, and the mechanical arm 212 is disposed on the sliding bracket 214. The sliding bracket 214 is operable to move along the slide rail 210 in the length direction of the transfer chamber 208, and the mechanical arm 212 may move together with the sliding bracket 214. In some embodiments, the mechanical arm 212 is fixedly mounted on the sliding bracket 214. That is, the mechanical arm 212 cannot move on the sliding bracket 214. In some other embodiments, the mechanical arm 212 is movably mounted on the sliding bracket 214. That is, the mechanical arm 212 can move on the sliding bracket 214 in a small range. In other embodiments of this application, the mechanical arm 212 may be disposed on the slide rail 210 and move along the slide rail 210 in other manners instead of using the sliding bracket 214.

The mechanical arm 212 has an extending arm portion. Because the arm portion is stretchable in length (for example, the arm portion may include a foldable or stretchable portion), a front end of the arm portion may extend to a specified position (for example, within the LL chamber 218 or the EFEM 202). The front end of the arm portion may include an apparatus such as a vane, a paddle, a fork or a jig for supporting or holding the substrate. The mechanical arm 212 may include one arm portion, or may include a plurality of arm portions to simultaneously transfer a plurality of substrates. In a case that the slide rail 210 is relatively long and the mechanical arm 212 may need to move a relatively long distance along the slide rail 210 to transfer the substrate, the transfer stability of the mechanical arm 212 and the equipment reliability need to be improved. For example, stable transfer and accurate positioning can be achieved by means of carefully designing structures of the slide rail 210 and the mechanical arm 212 and a connection structure between the slide rail and the mechanical arm, adopting a sensor(s), signal coordination, air flow control in a chamber and the like.

Two sides of the transfer chamber 208 may be provided with a plurality of valves 216-1, 216-2, 216-3, and 216-4 (collectively referred to as valves 216). In this embodiment, the transfer chamber 208 is located between the EFEM 202 and the LL chamber 218, and therefore may be an atmospheric transfer chamber. The valves 216 are atmospheric valves. Although FIG. 2 shows a specific quantity of valves 216, a person skilled in the art should understand that, the semiconductor processing system 200 may include fewer or more valves 216. The transfer chamber 208 is connected to the corresponding LL chamber 218 through the valve 216. For example, the transfer chamber 208 is connected to the LL chamber 218-1 through the valve 216-1, the transfer chamber 208 is connected to the LL chamber 218-2 through the valve 216-2, the transfer chamber 208 is connected to the LL chamber 218-3 through the valve 216-3, and the transfer chamber 208 is connected to the LL chamber 218-4 through the valve 216-4. The front end of the arm portion of the mechanical arm 212 is operable to pass through the valve 216 to enter the corresponding LL chamber 218, so as to place a to-be-processed substrate into the LL chamber 218 or take a processed substrate from the LL chamber 218.

The LL chamber 218 is located between the transfer chamber 208 and the processing chamber 206. The LL chamber 218 is connected to the corresponding processing chamber 206 through the vacuum valve 220. For example, the LL chamber 218-1 is connected to the processing chamber 206-1 through a vacuum valve 220-1, the LL chamber 218-2 is connected to the processing chamber 206-2 through a vacuum valve 220-2, the LL chamber 218-3 is connected to the processing chamber 206-1 through a vacuum valve 220-3, and the LL chamber 218-4 is connected to the processing chamber 206-2 through a vacuum valve 220-4. The LL chamber 218 may include a mechanical arm (not shown), and the mechanical arm is operable to: place the to-be-processed substrate into the processing chamber 206 (for example, to a processing station 232 in the processing chamber) through the vacuum valve 220, or take the processed substrate from the processing chamber 206 (for example, from a processing station 232 in the processing chamber) through the vacuum valve 220. In some embodiments, the mechanical arm may further receive the substrate from the mechanical arm 212 or transfer the substrate to the mechanical arm 212. In some embodiments, the mechanical arm may enter the transfer chamber 208 to receive the substrate from the mechanical arm 212 or transfer the substrate to the mechanical arm 212.

FIG. 2 shows the processing chambers 206-1 and 206-2 each including four processing stations. A dashed-line part in FIG. 2 represents that any quantity of valves and corresponding LL chambers and processing chambers may be disposed on both sides of the extending portion of the transfer chamber 208 in the length direction. Therefore, by increasing the length of the transfer chamber 208 and the length of the corresponding slide rail 210, a quantity of processing chambers carried in the semiconductor processing system 200 may be increased, thereby improving the integration level of the system and increasing the production capacity. A person skilled in the art should understand that, the semiconductor processing system 200 may include LL chambers and processing chambers with other shapes and/or configurations, and the processing chambers may include other quantities of processing stations. In some embodiments, the processing chamber may include an even quantity of processing stations. Positions, quantities, types, and the like of the valves, the LL chambers and the processing chambers on the two sides of the transfer chamber 208 may be the same, or may be different. The processing chamber in the semiconductor processing system 200 may be used to perform various semiconductor manufacturing processes such as deposition, etching, and cleaning on the substrate. The manufacturing processes performed by the processing chambers may be the same, or may be different.

The transfer chamber 208 is connected to the EFEM 202 on the first end. A door or another connection or communication structure may be disposed between the transfer chamber 208 and the EFEM 202. The front end of the mechanical arm 212 in the transfer chamber 208 is operable to enter the EFEM 202, so as to take a to-be-processed substrate from the EFEM 202 or place a processed substrate into the EFEM 202.

The EFEM 202 may include a mechanical arm 226. The mechanical arm 226 is operable to transfer the substrate between a substrate carrier 230 and the mechanical arm 212. The mechanical arm 226 has an extending arm portion. Because the arm portion is stretchable in length (for example, the arm portion may include a foldable or stretchable portion), a front end of the arm portion may extend to a specified position (for example, to the mechanical arm 212 or within the substrate carrier 230). The front end of the arm portion may include an apparatus such as a vane, a paddle, a fork or a jig for supporting or holding the substrate. The mechanical arm 226 may include one arm portion, or may include a plurality of arm portions to simultaneously transfer a plurality of substrates. FIG. 2 shows four substrate carriers 230 located on one end of the EFEM 202. It should be understood that, additionally or alternatively, the substrate carrier(s) 230 may be disposed on other position(s) (for example, on the two sides) of the EFEM 202, and fewer or more substrate carriers 230 may be optionally included. The mechanical arm 226 is operable to: take a to-be-processed substrate from any substrate carrier 230 through a door (not shown) between the EFEM 202 and the substrate carrier 230, and then transfer the to-be-processed substrate to the mechanical arm 212. The mechanical arm 226 is further operable to: receive the processed substrate from the mechanical arm 212, and then place the processed substrate into any substrate carrier 230 through the door (not shown) between the EFEM 202 and the substrate carrier 230. In some embodiments, the mechanical arm 226 may enter the transfer chamber 208 to receive the substrate from the mechanical arm 212 or transfer the substrate to the mechanical arm 212.

In some embodiments, the EFEM 202 may include a slide rail 228. The mechanical arm 226 may be disposed on the slide rail 228, and is operable to move along the slide rail 228 to different positions to transfer the substrates. The mechanical arm 226 may be disposed on the slide rail 228 by using a bracket (not shown) or another connection structure. In the example of FIG. 2, the slide rail 228 includes one rail. It should be understood that, in other embodiments, the slide rail 228 may include rails with another quantity and/or in another form. In other embodiments of this application, the mechanical arm 226 may move in another manner instead of using the slide rail, or the mechanical arm 226 does not move, but transfers the substrate only by using the extending arm portion.

A manner of transferring a substrate in the semiconductor processing system 200 is described below with reference to FIG. 2. When a substrate needs to be processed, the to-be-processed substrate is disposed in the substrate carrier 230. The mechanical arm 212 moves to a position near the first end of the transfer chamber 208. The mechanical arm 226 takes the to-be-processed substrate from the substrate carrier 230, and transfers the to-be-processed substrate to the mechanical arm 212. The mechanical arm 212 moves to a position near the LL chamber 218 corresponding to the processing chamber 206 in which the required processing is to be performed. The corresponding vacuum valve 220 of the LL chamber 218 is closed, the corresponding atmospheric valve 216 is opened, and the LL chamber 218 is restored to an atmospheric environment. The mechanical arm 212 transfers the to-be-processed substrate to the LL chamber 218. Then, the atmospheric valve 216 is closed. After the LL chamber 218 is vacuumized, the corresponding vacuum valve 220 is opened. The mechanical arm in the LL chamber 218 transfers the to-be-processed substrate to the processing chamber 206 through the vacuum valve 220. After the vacuum valve 220 is closed, the required processing is performed on the substrate. After the processing is completed, the vacuum valve 220 is opened, and the mechanical arm in the LL chamber 218 takes the processed substrate from the processing chamber 206 to the LL chamber 218. Then, the vacuum valve 220 is closed, the atmospheric valve 216 is opened, and the LL chamber 218 is restored to an atmospheric environment. The mechanical arm 212 takes the processed substrate from the LL chamber 218. If the substrate needs to be further processed in another processing chamber, the mechanical arm 212 may transfer the substrate to the another processing chamber; otherwise, the mechanical arm 212 moves to a position near the first end of the transfer chamber 208, and transfers the processed substrate to the mechanical arm 226. The mechanical arm 226 then transfers the processed substrate to the substrate carrier 230.

This application provides a substrate transfer module and a semiconductor processing system including the substrate transfer module, which can improve the integration level of the semiconductor processing system and increase the production capacity.

The descriptions in this specification are provided to enable a person skilled in the art to implement or use the present invention. Apparently, a person skilled in the art would easily make various variations or modifications to the present invention, and a generic principle defined in the specification may be applied to the variations or modifications without departing from the spirit or scope of the present invention. Therefore, the present invention is not limited to the examples and designs described in this specification, but is given the broadest scope consistent with the principle and novel features disclosed in this specification.

What is claimed is:

1. A substrate transfer module, comprising:
a transfer chamber, having a first end and a second end in a length direction, and having a first side and a second side in a width direction;
a slide rail, disposed in the transfer chamber, and extending in the length direction of the transfer chamber; and
a mechanical arm, disposed on the slide rail and having an extending arm portion, wherein the mechanical arm is operable to move along the slide rail in the length direction of the transfer chamber to transfer a substrate between an equipment front end module (EFEM) and a processing chamber, and wherein the EFEM is located at the first end of the transfer chamber, and the processing chamber is located on the first side or the second side of the transfer chamber.

2. The substrate transfer module according to claim 1, further comprising a sliding bracket, wherein the sliding bracket is disposed on the slide rail, and operable to move along the slide rail in the length direction of the transfer chamber, and the mechanical arm is disposed on the sliding bracket.

3. The substrate transfer module according to claim 1, wherein the first side and the second side of the transfer chamber are provided with a plurality of valves, and a front end of the arm portion of the mechanical arm is operable to pass through the plurality of valves.

4. The substrate transfer module according to claim 1, wherein the transfer chamber comprises a vacuum transfer chamber.

5. The substrate transfer module according to claim 4, wherein the transfer chamber is connected to the processing chamber through a valve on the first side or the second side, and the mechanical arm is operable to:
place a to-be-processed substrate into the processing chamber through the valve; and
take a processed substrate from the processing chamber through the valve.

6. The substrate transfer module according to claim 4, wherein the transfer chamber is connected to a load lock (LL) chamber located between the transfer chamber and the EFEM through a vacuum valve on the first end.

7. The substrate transfer module according to claim 6, wherein the mechanical arm is operable to:
take a to-be-processed substrate from the LL chamber through the vacuum valve; and
place a processed substrate into the LL chamber through the vacuum valve.

8. The substrate transfer module according to claim 1, wherein the transfer chamber comprises an atmospheric transfer chamber.

9. The substrate transfer module according to claim 8, wherein the transfer chamber is connected to the EFEM, and the mechanical arm is operable to:
take a to-be-processed substrate from the EFEM; and
place a processed substrate into the EFEM.

10. The substrate transfer module according to claim 8, wherein the transfer chamber is connected to an LL chamber located between the transfer chamber and the processing chamber through an atmospheric valve on the first side or the second side.

11. The substrate transfer module according to claim 10, wherein the mechanical arm is operable to:
place a to-be-processed substrate into the LL chamber through the atmospheric valve; and
take a processed substrate from the LL chamber through the atmospheric valve.

12. A semiconductor processing system, comprising:
the substrate transfer module according to claim 1;
an equipment front end module (EFEM); and
a processing chamber.

13. The semiconductor processing system according to claim 12, wherein the substrate transfer module further comprises a sliding bracket, the sliding bracket is disposed on the slide rail and operable to move along the slide rail in the length direction of the transfer chamber, and the mechanical arm is disposed on the sliding bracket.

14. The semiconductor processing system according to claim 12, wherein the first side and the second side of the transfer chamber are provided with a plurality of valves, and a front end of the arm portion of the mechanical arm is operable to pass through the plurality of valves.

15. The semiconductor processing system according to claim 12, wherein the transfer chamber comprises a vacuum transfer chamber.

16. The semiconductor processing system according to claim 15, wherein the transfer chamber is connected to the processing chamber through a valve on the first side or the second side, and the mechanical arm is operable to:
place a to-be-processed substrate into the processing chamber through the valve; and
take a processed substrate from the processing chamber through the valve.

17. The semiconductor processing system according to claim 15, further comprising: a load lock (LL) chamber located between the transfer chamber and the EFEM, wherein the transfer chamber is connected to the LL chamber through a vacuum valve on the first end, and the LL chamber is connected to the EFEM through an atmospheric valve.

18. The semiconductor processing system according to claim 17, wherein the mechanical arm is operable to:
take a to-be-processed substrate from the LL chamber through the vacuum valve; and
place a processed substrate into the LL chamber through the vacuum valve.

19. The semiconductor processing system according to claim 17, wherein the EFEM comprises a second mechanical arm, and the second mechanical arm is operable to:
place a to-be-processed substrate into the LL chamber through the atmospheric valve; and
take a processed substrate from the LL chamber through the atmospheric valve.

20. The semiconductor processing system according to claim 19, wherein the EFEM comprises a second slide rail, and the second mechanical arm is disposed on the second slide rail and is operable to move along the second slide rail.

21. The semiconductor processing system according to claim 12, wherein the transfer chamber comprises an atmospheric transfer chamber.

22. The semiconductor processing system according to claim 21, wherein the transfer chamber is connected to the EFEM, and the mechanical arm is operable to:
take a to-be-processed substrate from the EFEM; and
place a processed substrate into the EFEM.

23. The semiconductor processing system according to claim 21, wherein the EFEM comprises a second mechanical arm, and the second mechanical arm is operable to:
transfer a to-be-processed substrate from a substrate carrier to the mechanical arm; and
transfer a processed substrate from the mechanical arm to the substrate carrier.

24. The semiconductor processing system according to claim 23, wherein the EFEM comprises a second slide rail, and the second mechanical arm is disposed on the second slide rail and is operable to move along the second slide rail.

25. The semiconductor processing system according to claim 21, further comprising: a load lock (LL) chamber located between the transfer chamber and the processing chamber, wherein the transfer chamber is connected to the LL chamber through an atmospheric valve on the first side or the second side, and the LL chamber is connected to the processing chamber through a vacuum valve.

26. The semiconductor processing system according to claim 25, wherein the mechanical arm is operable to:
place a to-be-processed substrate into the LL chamber through the atmospheric valve; and
take a processed substrate from the LL chamber through the atmospheric valve.

27. The semiconductor processing system according to claim 25, wherein the LL chamber comprises a second mechanical arm, and the second mechanical arm is operable to:
place a to-be-processed substrate into the processing chamber through the vacuum valve; and
take a processed substrate from the processing chamber through the vacuum valve.

28. The semiconductor processing system according to claim 12, wherein the processing chamber comprises an even quantity of processing stations.
